(19) United States
(12) Patent Application Publication
(10) Pub. No.: US 2008/0036467 A1
(43) Pub. Date: Feb. 14, 2008

(54) Appliance Fault Monitor

(76) Inventor: Richard George Arthur Butler, Dunedin (NZ)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(21) Appl. No.: 11/568,246

(22) PCT Filed: Jul. 6, 2005
(86) PCT No.: PCT/NZ05/00163

§ 371 Date: Jun. 13, 2007

(30) Foreign Application Priority Data
Jul. 6, 2004 (NZ) 533978

(51) Int. Cl. G01R 31/28

(52) U.S. Cl. 324/511

(57) ABSTRACT

An appliance fault monitor for protecting electrical appliances against fault currents flowing. The alternating current to an appliance load controlled by a phase angle conduction controlled switching device is monitored. The intended non-conduction angle is determined and any current flowing in that angle is indicative of a fault. Repeated indications cause a circuit breaker to disconnect the load.

### TECHNICAL FIELD

This invention relates to an appliance fault monitor for protecting electrical appliances against fault currents by monitoring AC currents to or in the appliance. In particular the invention enables the monitoring of faults in appliances using phase angle conduction control.

### BACKGROUND ART

Appliance faults (power devices short circuited, current leakage paths etc) or their onset will be reflected in changes in expected AC input current. It would be desirable to monitor such current and disable the appliance upon detection of an unexpected current flow. With modern appliances control of pumps, heaters, motors and the like may be accomplished by conduction angle control of the power devices and this complicates fault monitoring of the type described because of the effect on the AC input current waveforms.

U.S. Pat. No. 6,081,123 discloses the use of sampling AC current and voltage applied to a load to determine the nature of the load and thence fault conditions, but the technique described cannot satisfactorily test for faults in appliances using phase angle conduction control.

### DISCLOSURE OF INVENTION

It is an object of the present invention to provide an appliance fault monitor which is capable of monitoring faults in appliances of the type described.

Accordingly the invention consists in an alternating current appliance fault monitor for monitoring faults in appliances having a load controlled by a conduction angle controlled switching device comprising:

a current sensor for sensing current flow to said load;

a controller which receives as an input said sensed current from said current sensor;

and a circuit interrupter activated by said controller to disconnect input current from said appliance on the determination of a fault by said controller;

said controller programmed to:

sample said input current at intervals during alternating current half cycles;

determine the angle in a half cycle said switching device should not be conducting;

and to determine a fault status when said sampled current is non-zero in said half cycle angle for a predetermined number of half cycles and in response activate said circuit interrupter.

### BRIEF DESCRIPTION OF DRAWINGS

Preferred forms of the present invention will be described with reference to the accompanying drawings in which:

FIG. 1 shows a current waveform for a conduction angle controlled appliance,

FIG. 2 shows the waveform of FIG. 1 when known additional current loads are present,

FIG. 3 shows a block diagram of the circuit for one embodiment of the present invention.

FIG. 4 shows a block diagram of the circuit for a second embodiment of the present invention, and

### MODES FOR CARRYING OUT THE INVENTION

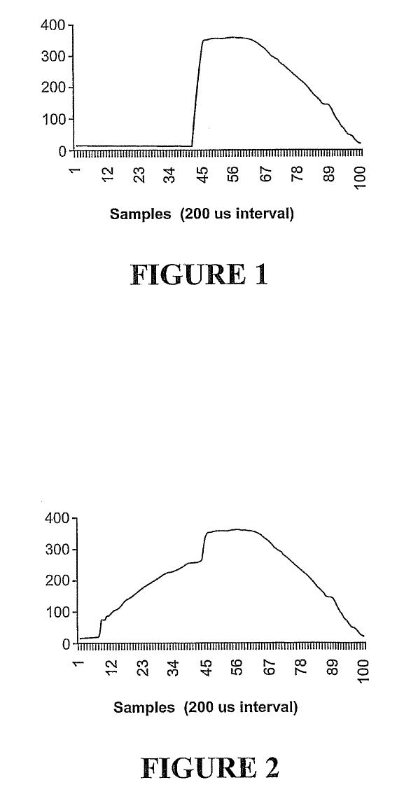

The invention detects electrical faults in AC electrical appliances which use phase angle control of power semiconductor devices such as IGBTs, SCRs and Triacs. This is done by monitoring instantaneous mains input current. The case where current is turned on during a half cycle by a controller and turned off at zero-crossings is shown in FIG. 1. If a fault develops in the power device or any current leakage path is established to ground then the mains current waveform will depart from that shown in FIG. 1. For the purposes of this disclosure the phase angle controlled device will be assumed to be an IGBT.

In a first embodiment the invention provides a discrete fault monitor which operates in the AC supply line to the appliance. In many appliances not all of the input AC current will be under the control of a power switch device operating under conduction angle control. For example in a dishwasher the water heater will normally be controlled by a simple ON/OFF device. Fault monitoring of the AC input current to such an appliance must therefore take into account loads of this type.

By way of example only, in the case of the dishwasher functions described in U.S. Pat. No. 6,469,920 where an IGBT is used to control power to pumps, then for a two tub dish washer described in U.S. Pat. No. 5,470,142 normal operation may see currents due to one or two water heaters switched on and one or two pumps on. FIG. 2 shows mains current when the dishwasher or one wash tub in a two tub appliance is in the wash cycle and being heated, ie one heater on and one pump on.

The mains current is sinusoidal dining a mains half cycle until the IGBT switches on. The magnitude of the sinusoidal current is equivalent to one heating element being turned on. Here faults are detected if the waveform departs from that shown—in magnitude over specific sections of the half cycles.

The fault monitor of the present invention monitors the mains current and senses
changes due to IGBT failure (short circuited), or
abnormal values of sinusoidal mains current due to leakage to ground for any reason and shuts off power to the appliance if faults are detected.

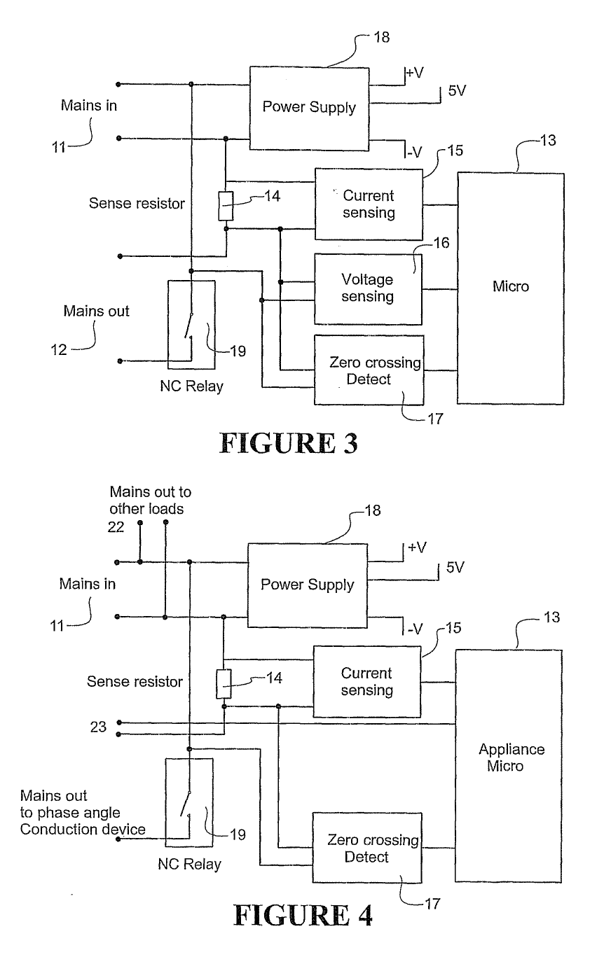

Referring to FIG. 3 the fault monitor has mains input terminals 11 and output terminals 12 to which an appliance is connected. The monitor has a controller 13 implemented by a programmed microprocessor. A sense resistor 14 and current sensing circuit 15 supply the controller 13 with a value of instantaneous 17 appliance input current.

A voltage sensing circuit 16 supplies controller 13 with a value representing instantaneous mains voltage. A mains zero-crossing detector circuit 17 provides controller 13 with timing information. These circuits are all supplied with operating DC voltage from power supply 18. A series relay (or interrupter) 19, which is normally closed, is activated by controller 13 to disconnect the appliance when a fault is determined by the stored program which executes the algorithms now described.

In the preferred form of the first embodiment current and voltage are measured by sampling at 200 μs intervals during each positive mains half cycle. A half cycle may be ignored when the peak current is below a measurement threshold value which is considered not to pose a risk.

A functioning IGTBT is indicated by detecting the “on” edge formed by the abrupt increase in measured current as the IGBT switches on during each mains half cycle. The magnitude of the sinusoidal current is estimated by calculating a resistance from the magnitude of the mains voltage and current samples immediately prior to detection of an IGBT “on” edge. When the current is below the measurement threshold value the resistance shall be set to an arbitrary large value.

A fault is declared when, for a specified number of consecutive half cycles
the IGBT “on” edge is not detected and a valid resistance is not present for more than half the mains half cycle time, or
the resistance is below the arbitrary large value and outside the tolerance ranges corresponding to one or both elements being on.

The number of half cycles can be decreased when the resistance is less than the equivalent of two elements or greater than the value of two motors priming, to male the response faster in these cases.

When the magnitude of the current immediately prior to the IGBT “on” edge is below the measurement threshold value and the IGBT “on” edge occurs in the last quarter of a mains half cycle the resistance shall be that calculated when the measured voltage is the maximum during the half cycle.

This device may be required to run on either 120V 60 Hz or 230V 50 Hz, depending on the market. This means that there will be two possible element designs. The mains frequency shall be measured by the controller and used to choose the appropriate range of effective resistance.

When a fault is declared the relay shall be switched off, removing power from the appliance. After waiting for the controllers to discharge, the relay shall be switched on again until another fault is declared. After the relay has been switched off five times it shall remain off until power is reapplied to the device, thereby re-initialising the software.

The number of consecutive faults required to reopen the relay shall be reduced to 100 for the first 511 mains cycles after a retry. This is to provide a faster response at a time when the controller is initialising and no current should be present before IGBT switch.

### If no faults are declared for a period of 48 hours the retry count is zeroed.

In a second embodiment the fault monitor is integrated with the appliance. That is, it is not a discrete apparatus which is simply connected in series with the appliance AC supply line.

In this embodiment the “on” transition time of the conduction angle controlled device does not need to be detected. The output of the appliance controller which determines this transition, the IGBT gate trigger signal, is used by the controller directly.

Further, AC input current to loads not under phase angle conduction control can be split off prior to the fault monitoring point. This means it is not necessary to calculate and monitor resistance and therefore that it is not necessary to sense the input voltage for this purpose.

Finally, the fault monitoring functions can be carried out by the main appliance controller thereby avoiding the cost of a second dedicated microprocessor.

FIG. 4 shows fault monitoring integrated with the appliance incorporating the savings and simplications mentioned above. Mains current for non IGBT controlled loads 22 is split off before the fault monitor circuit.

A current sensor 15 is regularly sampled by the appliance microcontroller 21. The detection of non zero current immediately prior to the IGBT trigger pulse (on controller output 23), when the IGBT should be off, is indicative of a fault. Repeated occurrences, as with the first embodiment, result in a fault being declared and relay 19 opened to prevent fault current from flowing.

In other respects the second embodiment functions as per the first embodiment.

1. An alternating current appliance fault monitor for monitoring faults in appliances having a load controlled by a conduction angle controlled switching device comprising:
a current sensor for sending current flow to said load;
a controller which receives as an input said sensed current from said current sensor;
and a circuit interrupter activated by said controller to disconnect input current from said appliance on the determination of a fault by said controller;
said controller programmed to:
sample said input current at intervals during alternating current half cycles;
determine the angle in a half cycle said switching device should not be conducting;
and to determine a fault status when said sampled current is non-zero in said half cycle angle for a predetermined number of half cycles and in response activate said circuit interrupter.

2. An alternative current appliance fault monitor according to claim 1 further comprising means for determining zero crossings of said alternating current,
means for generating a trigger pulse to cause said switching device to conduct
and wherein said controller is programmed to determine said angle of non-conduction as the angle between a current zero-crossing and the timing of the trigger pulse which causes said switching device to conduit.

3. An alternating current appliance fault monitor according to claim 1 further comprising a voltage sensor which senses the appliance input voltage and which supplies a further controller input,
and said controller further programmed to:
sample said input voltage simultaneously with said current sampling, repeatedly calculate a resistance from the voltage and current samples over a defined period of each half cycle, and to determine a fault status when said calculated resistance is below a predetermined value for a predetermined number of half cycles.

4. An alternating current appliance fault monitor according to claim 3 wherein said controller is programmed to determine from successive samples of input current when there is a sharp increase in current and to determine a fault and activate said circuit interrupter if said sharp increase is not detected and said resistance is below said predetermined value for more than half a half cycle.
